(19) United States
(12) Patent Application Publication
(10) Pub. No.: US 2026/0059813 A1
(43) Pub. Date: Feb. 26, 2026

(54) SEMICONDUCTOR STRUCTURE AND METHOD FOR PREPARING THE SAME

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 19/026,337

(22) Filed: Jan. 16, 2025

(30) Foreign Application Priority Data
Aug. 21, 2024 (CN) 202411154401.2

(51) Int. Cl. H10D 62/17; H01L 21/02; H10D 30/01; H10D 30/47; H10D 62/85; H10D 62/854

(52) U.S. Cl. CPC H10D 62/343; H01L 21/02694; H10D 30/015; H10D 30/4755; H10D 62/8503; H10D 62/854

(57) ABSTRACT

A semiconductor structure includes a substrate, a channel layer and a barrier layer which are stacked sequentially, the channel layer and the barrier layer including a gate region, a source region located at one side of the gate region and a drain region located at another one side of the gate region; and a P-type semiconductor layer, located at least in the gate region and located at a side, away from the substrate, of the barrier layer; where the P-type semiconductor layer includes a non-activated layer, an N-type doped layer and an activated layer which are stacked sequentially, and the non-activated layer is located on a side, close to the substrate, of the P-type semiconductor layer.

### CROSS-REFERENCE TO RELATED APPLICATIONS

The present disclosure claims priority to Chinese Patent Application No. 202411154401.2, filed on Aug. 21, 2024, the content of which is incorporated herein by reference in its entirety.

### TECHNICAL FIELD

The present disclosure relates to the field of semiconductor technologies, and in particular, to a semiconductor structure and a method for preparing the same.

### BACKGROUND

Compared with a first-generation semiconductor material and a second-generation semiconductor material, a third-generation semiconductor material, especially a GaN (gallium nitride)-based material has advantages of wide band gap, high breakdown field strength, high electron mobility, strong radiation resistance, and the like. The GaN-based High Electron Mobility Transistor (HEMT) device has great development potential in high-frequency and high-power fields such as wireless communication base stations, radars, automobile electronics, and the like.

In general, the GaN-based HEMT device is a depletion mode field effect transistor, but in an actual application scenario, taking into account factors such as actual cost and failure protection, an enhancement mode HEMT device is often required. There are many methods to implement an enhancement mode device, for example, a two-dimensional electron gas at a gate is depleted by disposing a P-type semiconductor. However, a P-type gate HEMT device still has problems of low output current density, high gate leakage current and low stability of device.

### SUMMARY

In view of this, embodiments of the present disclosure provide a semiconductor structure and a method for preparing the same to solve a problem of high gate leakage current of a P-type gate HEMT device.

According to an aspect of the present disclosure, an embodiment of the present disclosure provides a semiconductor structure, including: a substrate, a channel layer and a barrier layer which are stacked sequentially, the channel layer and the barrier layer including a gate region, a source region located at one side of the gate region and a drain region located at another one side of the gate region; and a P-type semiconductor layer, located at least in the gate region and located on a side, away from the substrate, of the barrier layer, where the P-type semiconductor layer includes a non-activated layer, an N-type doped layer and an activated layer which are stacked sequentially, and the non-activated layer is located on a side, close to the substrate, of the P-type semiconductor layer.

As an optional embodiment, a hydrogen concentration of the non-activated layer is greater than a hydrogen concentration of the activated layer.

As an optional embodiment, a thickness of the non-activated layer is less than a thickness of the activated layer.

As an optional embodiment, the N-type doped layer includes an N-type delta doped layer.

As an optional embodiment, N-type doped ions of the N-type doped layer include at least one of Si ions, Ge ions, Sn ions, Se ions or Te ions.

As an optional embodiment, a material of the P-type semiconductor layer includes a group III nitride material.

As an optional embodiment, P-type doped ions of the P-type semiconductor layer include at least one of Mg ions, Zn ions, Ca ions, Sr ions or Ba ions.

As an optional embodiment, the P-type semiconductor layer includes a first P-type region located in the gate region and a second P-type region located in a non-gate region, and a thickness of the first P-type region is greater than a thickness of the second P-type region.

As an optional embodiment, a surface of a side, away from the substrate, of the second P-type region is the N-type doped layer.

As an optional embodiment, a thickness of the N-type doped layer located in the second P-type region is less than or equal to a thickness of the N-type doped layer located in the first P-type region.

As an optional embodiment, a side, close to the substrate, of the second P-type region, is the non-activated layer.

As an optional embodiment, the semiconductor structure further includes: a gate, located in the gate region and located on a side, away from the substrate, of the P-type semiconductor layer; a source, located in the source region and located on a side, away from the substrate, of the channel layer; and a drain, located in the drain region and located on a side, away from the substrate, of the channel layer.

According to another aspect of the present disclosure, an embodiment of the present disclosure provides a method for preparing a semiconductor structure, including the following Step S1 to Step S4.

S1, disposing a substrate, a channel layer, a barrier layer and a P-type semiconductor layer which are stacked sequentially, the channel layer and the barrier layer including a gate region, a source region located at one side of the gate region and a drain region located at another one side of the gate region.

S2, etching the P-type semiconductor layer, at least the P-type semiconductor layer on the gate region of the barrier layer being retained.

S3, forming an N-type doped layer in the P-type semiconductor layer.

S4, activating, by high temperature annealing, the P-type semiconductor layer on a side, away from the substrate, of the N-type doped layer to form an activated layer, where the P-type semiconductor layer on a side, close to the substrate, of the N-type doped layer is not activated, forming a non-activated layer.

As an optional embodiment, a thickness of the non-activated layer is less than a thickness of the activated layer.

As an optional embodiment, a method for forming the N-type doped layer in the Step S3 is ion implantation of N-type ions to form a delta doped layer.

As an optional embodiment, after etching the P-type semiconductor layer in the Step S2, a first P-type region in the gate region and a second P-type region in a non-gate region are retained, and a thickness of the first P-type region is greater than a thickness of the second P-type region.

As an optional embodiment, a surface of a side, away from the substrate, of the second P-type region is the N-type doped layer.

As an optional embodiment, a thickness of the N-type doped layer located in the second P-type region is less than or equal to a thickness of the N-type doped layer located in the first P-type region.

As an optional embodiment, a side, close to the substrate, of the second P-type region is the non-activated layer.

As an optional embodiment, the method for preparing a semiconductor structure further includes Step S5.

S5, disposing a gate in the gate region and on a side, away from the substrate, of the P-type semiconductor layer; disposing a source in the source region and on a side, away from the substrate, of the channel layer; and disposing a drain in the drain region and on a side, away from the substrate, of the channel layer.

### BRIEF DESCRIPTION OF THE DRAWINGS

FIG. 1 is a schematic structural diagram of a semiconductor structure according to an embodiment of the present disclosure.

FIG. 2 and FIG. 3 are schematic structural diagrams of semiconductor structures according to some embodiments of the present disclosure.

FIG. 4 is a schematic flowchart of a method for preparing a semiconductor structure according to an embodiment of the present disclosure.

FIG. 5 to FIG. 8 are schematic diagrams of intermediate structures corresponding to processes in FIG. 4.

### DETAILED DESCRIPTION OF THE EMBODIMENTS

The following clearly describes technical solutions in the embodiments of the present disclosure with reference to the accompanying drawings in the embodiments of the present disclosure. Apparently, the described embodiments are a part rather than all of the embodiments of the present disclosure. All other embodiments obtained by a person skilled in the art based on the embodiments of the present disclosure without creative efforts shall fall within the protection scope of the present disclosure.

In order to solve a problem of high gate leakage current of a P-type gate HEMT device, the present disclosure provides a semiconductor structure and a method for preparing the same. The semiconductor structure includes a substrate, a channel layer and a barrier layer which are stacked sequentially, the channel layer and the barrier layer including a gate region, a source region located at one side of the gate region and a drain region located at another one side of the gate region; and a P-type semiconductor layer, located at least in the gate region and located at a side, away from the substrate, of the barrier layer. The P-type semiconductor layer includes a non-activated layer, an N-type doped layer and an activated layer which are stacked sequentially, and the non-activated layer is located on a side, close to the substrate, of the P-type semiconductor layer. The design of the N-type doped layer of the present disclosure may enable the P-type semiconductor layer to have an activated layer and a non-activated layer, the activated layer is configured to ensure a normally-off state of the semiconductor structure, and the non-activated layer is configured to reduce gate leakage current and improve reliability of device.

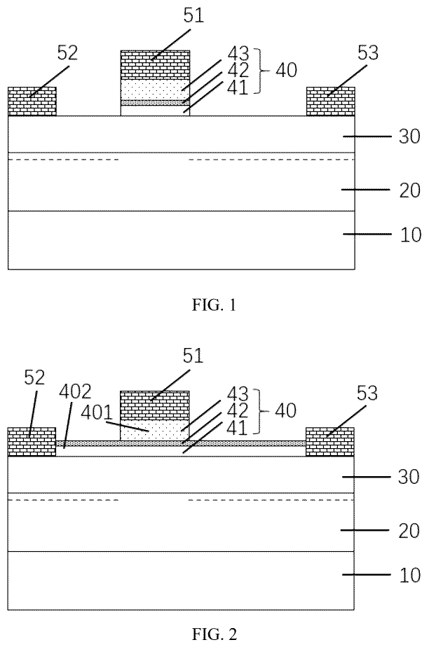

The semiconductor structure and a method for preparing the same mentioned in the present disclosure are further illustrated below with reference to FIG. 1 to FIG. 8.

FIG. 1 is a schematic structural diagram of a semiconductor structure according to an embodiment of the present disclosure. As shown in FIG. 1, the semiconductor structure includes a substrate 10, a channel layer 20 and a barrier layer 30 which are stacked sequentially, the channel layer 20 and the barrier layer 30 including a gate region, a source region located at one side of the gate region and a drain region located at another one side of the gate region; and a P-type semiconductor layer 40, located at least in the gate region and located at a side, away from the substrate 10, of the barrier layer 30. The P-type semiconductor layer 40 includes a non-activated layer 41, an N-type doped layer 42 and an activated layer 43 which are stacked sequentially, and the non-activated layer 41 is located on a side, close to the substrate 10, of the P-type semiconductor layer 40.

In an embodiment, a material of the substrate 10 includes any one or a combination of any of Si, sapphire, GaN, SiC, AlN or diamond. A material of the channel layer 20 and a material of the barrier layer 30 may include a group III nitride material, and a two-dimensional electron gas may be formed at an interface between the channel layer 20 and the barrier layer 30. In an optional solution, the channel layer 20 is a GaN layer, and the barrier layer 30 is an AlGaN layer. In other optional solutions, a combination of material of the channel layer 20 and the barrier layer 30 may also be GaN/AlN, GaN/InN, GaN/InAlGaN, GaAs/AlGaAs, GaN/InAlN or InN/InAlN. A material of the P-type semiconductor layer 40 includes a group III nitride material, and P-type doped ions of the P-type semiconductor layer 40 include at least one of Mg ions, Zn ions, Ca ions, Sr ions or Ba ions.

In an embodiment, the P-type semiconductor layer 40 includes a non-activated layer 41, an N-type doped layer 42 and an activated layer 43 which are stacked sequentially in a direction away from the substrate 10. A hydrogen concentration of the non-activated layer 41 is greater than a hydrogen concentration of the activated layer 43. The gate leakage current may be reduced and the reliability of the device may be improved due to the disposing of the non-activated layer 41. A thickness of the non-activated layer 41 is less than a thickness of the activated layer 43, which may reduce impact of the presence of the non-activated layer 41 on the ability of the activated layer 43 to deplete the two-dimensional electron gas. The N-type doped layer 42 includes an N-type delta doped layer, and N-type doped ions of the N-type doped layer 42 include at least one of Si ions, Ge ions, Sn ions, Se ions or Te ions. The N-type doped layer 42 may form a PN junction with the P-type semiconductor layer 40, so the interface electric field between the gate metal and the semiconductor structure may be adjusted to further suppress the gate leakage current.

In an embodiment, the semiconductor structure may further include a nucleation layer and a buffer layer (not shown in FIG. 1) between the substrate 10 and the channel layer 20. Depending on the design requirements, for example, the nucleation layer and the buffer layer may be disposed to improve the quality of the semiconductor layer grown on the substrate 10. Taking growth of GaN on the silicon substrate as an example, the nucleation layer and the buffer layer are usually disposed to improve the subsequent growth quality of GaN. For example, the nucleation layer may adopt AlN, and the buffer layer may adopt AlGaN, GaN or InGaN. The present disclosure is not limited thereto, the nucleation layer and the buffer layer may be determined depending on the material of the substrate 10 and the material of the channel layer 20. For example, when the GaN is grown on the gallium nitride substrate, the nucleation layer and the buffer layer may also be omitted, or only one of the nucleation layer and the buffer layer may be disposed on the gallium nitride substrate.

In an embodiment, as shown in FIG. 1, the semiconductor structure further includes: a gate 51, located in the gate region and located on a side, away from the substrate 10, of the P-type semiconductor layer 40; a source 52, located in the source region and located on a side, away from the substrate 10, of the channel layer 30; and a drain 53, located in the drain region and located on a side, away from the substrate 10, of the channel layer 30.

It should be noted that FIG. 1 only illustrates that the source 52 and the drain 53 are located on a side, away from the substrate 10, of the barrier layer 30. Optionally, the barrier layer 30 may be thinned at positions corresponding to the source 52 and the drain 53. Optionally, the source 52 and the drain 53 penetrate through the barrier layer 30 to be in direct contact with the channel layer 20.

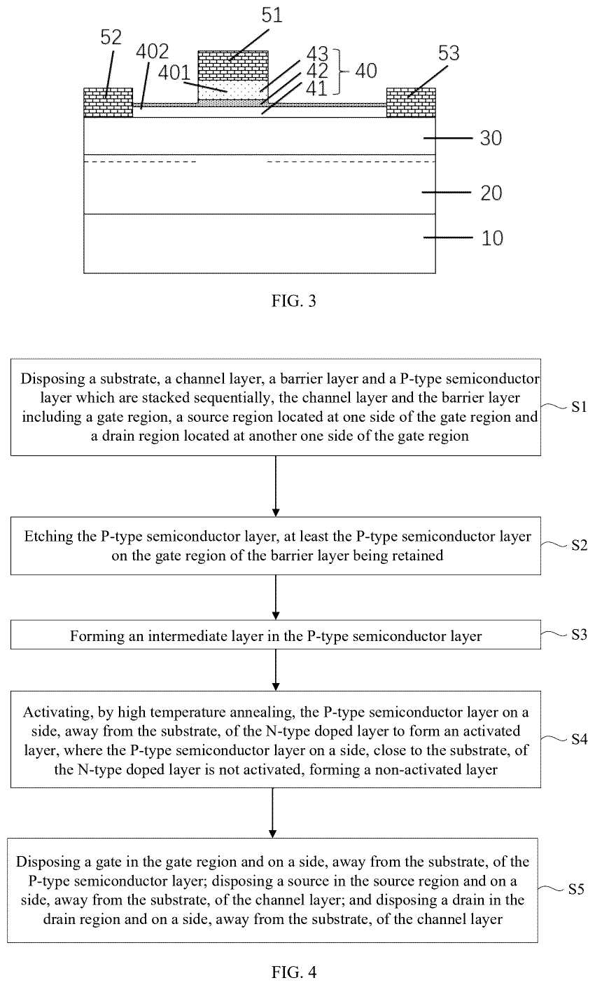

In an embodiment, FIG. 2 to FIG. 3 are schematic structural diagrams of semiconductor structures according to some embodiments of the present disclosure. As shown in FIG. 2, the P-type semiconductor layer 40 includes a first P-type region 401 located in the gate region and a second P-type region 402 located in a non-gate region. A thickness of the first P-type region 401 is greater than a thickness of the second P-type region 402. Due to the disposing of the second P-type region 402, the surface quality of the barrier layer 30 is not damaged when the P-type semiconductor layer 40 is formed by etching. Since a surface of a side, away from the substrate 10, of the second P-type region 402 is N-type doped layer 42, and a side, close to the substrate 10, of the second P-type region 402 is non-activated layer 41, the channel conduction capability may be ensured without affecting the two-dimensional electron gas. In the semiconductor structure shown in FIG. 2, the thickness of the N-type doped layer 42 located in the second P-type region 402 is equal to the thickness of the N-type doped layer 42 located in the first P-type region 401. Optionally, as shown in FIG. 3, the thickness of the N-type doped layer 42 located in the second P-type region 402 is less than the thickness of the N-type doped layer 42 located in the first P-type region 401. The thickness of the N-type doped layer 42 located in the second P-type region 402 is not specifically limited in the present disclosure, as long as a side, close to the substrate 10, of the second P-type region 402 is not activated.

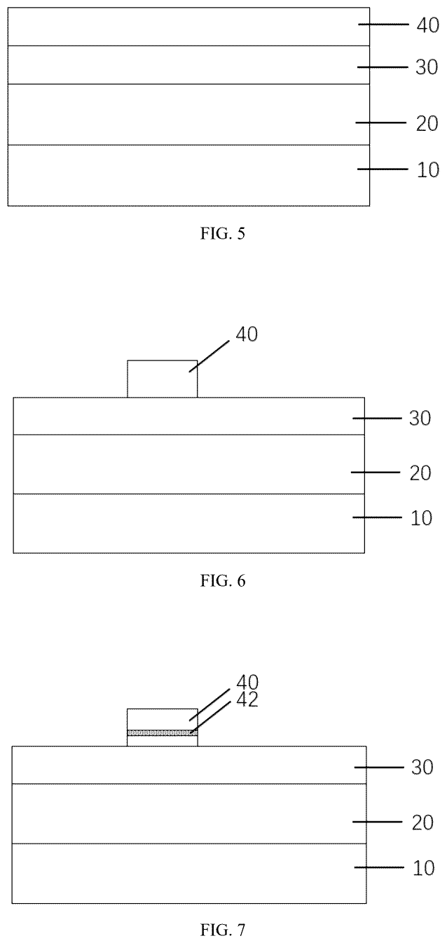

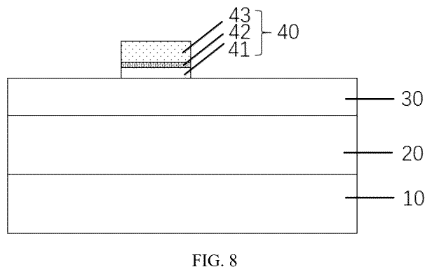

According to another aspect of the present disclosure, an embodiment of the present disclosure provides a method for preparing a semiconductor structure. FIG. 4 is a schematic flowchart of a method for preparing a semiconductor structure according to an embodiment of the present disclosure. FIG. 5 to FIG. 8 are schematic diagrams of intermediate structures corresponding to processes in FIG. 4. As shown in FIG. 4, a method for preparing a semiconductor structure provided by an embodiment of the present disclosure includes the following Step S1 to Step S5.

Step S1: disposing a substrate, a channel layer, a barrier layer and a P-type semiconductor layer which are stacked sequentially, the channel layer and the barrier layer including a gate region, a source region located at one side of the gate region and a drain region located at another one side of the gate region.

Specifically, as shown in FIG. 5, the substrate 10, the channel layer 20, the barrier layer 30 and the P-type semiconductor layer 40 are sequentially stacked. The channel layer 20 and the barrier layer 30 include a gate region, a source region located at one side of the gate region and a drain region located at another one side of the gate region. A material of the substrate 10 includes any one or a combination of any of Si, sapphire, GaN, SiC, AlN or diamond. A material of the channel layer 20 and a material of the barrier layer 30 may include a group III nitride material, and a two-dimensional electron gas may be formed at an interface between the channel layer 20 and the barrier layer 30. A method for growing the channel layer 20 and the barrier layer 30 may be Atomic Layer Deposition (ALD), Chemical Vapor Deposition (CVD), Molecular Beam Epitaxy (MBE), Plasma Enhanced Chemical Vapor Deposition (PECVD), Low Pressure Chemical Vapor Deposition (LPCVD) or Metal-Organic Chemical Vapor Deposition (MOCVD) or a combination thereof. A material of the P-type semiconductor layer 40 includes a group III nitride material, and P-type doped ions of the P-type semiconductor layer 40 include at least one of Mg ions, Zn ions, Ca ions, Sr ions or Ba ions.

Step S2: etching the P-type semiconductor layer, at least the P-type semiconductor layer on the gate region of the barrier layer being retained.

Specifically, as shown in FIG. 6, the P-type semiconductor layer 40 is etched to retain at least the P-type semiconductor layer 40 on the gate region of the barrier layer 30.

Step S3: forming an N-type doped layer in the P-type semiconductor layer.

Specifically, as shown in FIG. 7, an N-type doped layer 42 is formed in the P-type semiconductor layer 40. A method for forming the N-type doped layer 42 is ion implantation of N-type ions to form a delta doped layer. The N-type doped ions include at least one of Si ions, Ge ions, Sn ions, Se ions or Te ions.

Step S4: activating, by high temperature annealing, the P-type semiconductor layer on a side, away from the substrate, of the N-type doped layer to form an activated layer, where the P-type semiconductor layer on a side, close to the substrate, of the N-type doped layer is not activated, forming a non-activated layer.

Specifically, as shown in FIG. 8, the P-type semiconductor layer 40 on a side, away from the substrate 10, of the N-type doped layer 42 is activated by high temperature annealing to form an activated layer 43. The P-type semiconductor layer 40 on a side, close to the substrate 10, of the N-type doped layer 42 is not activated, forming a non-activated layer 41. A hydrogen concentration of the non-activated layer 41 is greater than a hydrogen concentration of the activated layer 43, and the gate leakage current may be reduced and the reliability of the device may be improved due to the disposing of the non-activated layer 41. A thickness of the non-activated layer 41 is less than a thickness of the activated layer 43, which may reduce impact of the presence of the non-activated layer 41 on the ability of the active layer 43 to deplete the two-dimensional electron gas. Due to the disposing of the N-type doped layer 42, on one hand, the N-type doped layer 42 may be used as a barrier layer to prevent one side, close to the substrate 10, of the P-type semiconductor layer 40 from being activated, so that the P-type semiconductor layer 40 has a non-activated layer 41; on the other hand, the N-type doped layer 42 may form a PN junction with the P-type semiconductor layer 40, so that the interface electric field between the gate metal and the semiconductor structure may be adjusted to further suppress the gate leakage current.

In an embodiment, the method for preparing a semiconductor structure further includes Step S5.

Step S5: disposing a gate in the gate region and on a side, away from the substrate, of the P-type semiconductor layer; disposing a source in the source region and on a side, away from the substrate, of the channel layer; and disposing a drain in the drain region and on a side, away from the substrate, of the channel layer.

Specifically, a gate 51 is disposed in the gate region and on a side, away from the substrate 10, of the P-type semiconductor layer 40. A source 52 is disposed in the source region and on a side, away from the substrate 10, of the channel layer 30. A drain 53 is disposed in the drain region and on a side, away from the substrate 10, of the channel layer 30, and the semiconductor structure as shown in FIG. 1 is formed.

In an embodiment, after etching the P-type semiconductor layer 40 in the Step S2, a first P-type region 401 in the gate region and a second P-type region 402 in a non-gate region are retained, and a thickness of the first P-type region 401 is greater than a thickness of the second P-type region 402, and the semiconductor structure as shown in FIG. 2 is formed. Due to the disposing of the second P-type region 402, the surface quality of the barrier layer 30 is not damaged when the P-type semiconductor layer 40 is formed by etching. Since a surface of a side, away from the substrate 10, of the second P-type region 402 is N-type doped layer 42, and a side, close to the substrate 10, of the second P-type region 402 is non-activated layer 41, the channel conduction capability may be ensured without affecting the two-dimensional electron gas. In the semiconductor structure shown in FIG. 2, a thickness of the N-type doped layer 42 located in the second P-type region 402 is equal to a thickness of the N-type doped layer 42 located in the first P-type region 401. Optionally, as shown in FIG. 3, the thickness of the N-type doped layer 42 located in the second P-type region 402 is less than the thickness of the N-type doped layer 42 located in the first P-type region 401. The thickness of the N-type doped layer 42 located in the second P-type region 402 is not specifically limited in the present disclosure, as long as a side, close to the substrate 10, of the second P-type region 402 is not activated.

The present disclosure provides a semiconductor structure and a method for preparing the same. The semiconductor structure includes a substrate, a channel layer and a barrier layer which are stacked sequentially, the channel layer and the barrier layer including a gate region, a source region located at one side of the gate region and a drain region located at another one side of the gate region; and a P-type semiconductor layer, located at least in the gate region and located at a side, away from the substrate, of the barrier layer. The P-type semiconductor layer includes a non-activated layer, an N-type doped layer and an activated layer which are stacked sequentially, and the non-activated layer is located on a side, close to the substrate, of the P-type semiconductor layer. In the conventional technology, P-type semiconductor material needs to be annealed at a high temperature, a bonding junction of a Mg—H complex in the P-type semiconductor material is cut off and an H atom is driven off to implement P-type activation. A N-type doped layer is designed in the P-type semiconductor material to block the dissipation path of the H atom in the P-type semiconductor material below the N-type doped layer, resulting in that the P-type semiconductor material below the N-type doped layer cannot be activated. Therefore, the design of the N-type doped layer of the present disclosure may enable the P-type semiconductor layer to have an activated layer and a non-activated layer, the activated layer is configured to deplete the two-dimensional electron gas in the channel of the gate region to ensure a normally-off state of the semiconductor structure, and the non-activated layer is configured to reduce gate leakage current formed by leakage from the channel to the gate in the device and block the influence of the surface state of the semiconductor structure on the channel in the gate region, thereby improving the reliability of the device.

It should be understood that the terms “include” and variations thereof used in the present disclosure are open ended, that is, “including, but not limited to”. The term “an embodiment” means “at least one embodiment”. The term “another embodiment” means “at least one other embodiment”. In this specification, the schematic expressions of the above terms do not necessarily refer to the same embodiments or examples. In addition, the specific features, structures, materials or characteristics described may be combined in any suitable manner in any one or more embodiments or examples. In addition, in the case of no contradiction, a person skilled in the art may combine and integrate different embodiments or examples and features from different embodiments or examples described in the present disclosure.

The above are only preferred embodiments of the present disclosure, and are not intended to limit the protection scope of the present disclosure. Any modification, equivalent replacement, improvement and the like made within the spirit and principle of this disclosure shall be included within the protection scope of this disclosure.

What is claimed is:

1. A semiconductor structure, comprising:
a substrate, a channel layer and a barrier layer which are stacked sequentially, the channel layer and the barrier layer comprising a gate region, a source region located at one side of the gate region and a drain region located at another one side of the gate region; and
a P-type semiconductor layer, located at least in the gate region and located on a side, away from the substrate, of the barrier layer;
wherein the P-type semiconductor layer comprises a non-activated layer, an N-type doped layer and an activated layer which are stacked sequentially, and the non-activated layer is located on a side, close to the substrate, of the P-type semiconductor layer.

2. The semiconductor structure according to claim 1, wherein a hydrogen concentration of the non-activated layer is greater than a hydrogen concentration of the activated layer.

3. The semiconductor structure according to claim 1, wherein a thickness of the non-activated layer is less than a thickness of the activated layer.

4. The semiconductor structure according to claim 1, wherein the N-type doped layer comprises an N-type delta doped layer.

5. The semiconductor structure according to claim 4, wherein N-type doped ions of the N-type doped layer comprise at least one of Si ions, Ge ions, Sn ions, Se ions or Te ions.

6. The semiconductor structure according to claim 1, wherein a material of the P-type semiconductor layer comprises a group III nitride material.

7. The semiconductor structure according to claim 6, wherein P-type doped ions of the P-type semiconductor layer comprise at least one of Mg ions, Zn ions, Ca ions, Sr ions or Ba ions.

8. The semiconductor structure according to claim 1, wherein the P-type semiconductor layer comprises a first P-type region located in the gate region and a second P-type region located in a non-gate region, and a thickness of the first P-type region is greater than a thickness of the second P-type region.

9. The semiconductor structure according to claim 8, wherein a surface of a side, away from the substrate, of the second P-type region is the N-type doped layer.

10. The semiconductor structure according to claim 9, wherein a thickness of the N-type doped layer located in the second P-type region is less than or equal to a thickness of the N-type doped layer located in the first P-type region.

11. The semiconductor structure according to claim 8, wherein a side, close to the substrate, of the second P-type region, is the non-activated layer.

12. The semiconductor structure according to claim 1, further comprising:
a gate, located in the gate region and located on a side, away from the substrate, of the P-type semiconductor layer;
a source, located in the source region and located on a side, away from the substrate, of the channel layer; and
a drain, located in the drain region and located on a side, away from the substrate, of the channel layer.

13. A method for preparing a semiconductor structure, comprising:
S1, disposing a substrate, a channel layer, a barrier layer and a P-type semiconductor layer which are stacked sequentially, the channel layer and the barrier layer comprising a gate region, a source region located at one side of the gate region and a drain region located at another one side of the gate region;
S2, etching the P-type semiconductor layer, at least the P-type semiconductor layer on the gate region of the barrier layer being retained;
S3, forming an N-type doped layer in the P-type semiconductor layer; and
S4, activating, by high temperature annealing, the P-type semiconductor layer on a side, away from the substrate, of the N-type doped layer to form an activated layer, wherein the P-type semiconductor layer on a side, close to the substrate, of the N-type doped layer is not activated, forming a non-activated layer.

14. The method according to claim 13, wherein a thickness of the non-activated layer is less than a thickness of the activated layer.

15. The method according to claim 13, wherein a method for forming the N-type doped layer in the Step S3 is ion implantation of N-type ions to form a delta doped layer.

16. The method according to claim 13, wherein after etching the P-type semiconductor layer in the Step S2, a first P-type region in the gate region and a second P-type region in a non-gate region are retained, and a thickness of the first P-type region is greater than a thickness of the second P-type region.

17. The method according to claim 16, wherein a surface of a side, away from the substrate, of the second P-type region is the N-type doped layer.

18. The method according to claim 17, wherein a thickness of the N-type doped layer located in the second P-type region is less than or equal to a thickness of the N-type doped layer located in the first P-type region.

19. The method according to claim 16, wherein a side, close to the substrate, of the second P-type region is the non-activated layer.

20. The method according to claim 13, further comprising:
S5, disposing a gate in the gate region and on a side, away from the substrate, of the P-type semiconductor layer; disposing a source in the source region and on a side, away from the substrate, of the channel layer; and disposing a drain in the drain region and on a side, away from the substrate, of the channel layer.
